(19) United States
(12) Patent Application Publication
(10) Pub. No.: US 2026/0353887 A1
(43) Pub. Date: Nov. 5, 2026

(54) WIRING SUBSTRATE, LIGHT-EMITTING SUBSTRATE, AND DISPLAY DEVICE

(71) Applicants: Hefei BOE Ruisheng Technology Co., Ltd., Anhui (CN); BOE Technology Group Co., Ltd., Beijing (CN)

(72) Inventors: Chunjian LIU, Beijing (CN); Jian TIAN, Beijing (CN); Jie LEI, Beijing (CN); Jianying ZHANG, Beijing (CN); Yajun MA, Beijing (CN)

(21) Appl. No.: 19/124,470

(22) PCT Filed: Jun. 11, 2024
(86) PCT No.: PCT/CN2024/098493

§ 371 Date: Apr. 25, 2025

(30) Foreign Application Priority Data
Jul. 31, 2023 (CN) 202310960565.3

(51) Int. Cl. H10H 29/49

(52) U.S. Cl. CPC H10H 29/49

(57) ABSTRACT

Disclosed in the present disclosure are a wiring substrate, a light-emitting substrate, and a display device, which are used to avoid poor brightness of a last-stage lamp area in a cascade lamp area. The wiring substrate comprises a base substrate, the base substrate being divided into a functional region and a bonding region; wherein the functional region comprises a plurality of pad units arranged along a first direction and a second direction respectively, wherein the pad unit comprises: a first pad region, and a second pad region electrically connected to the first pad region, and the second direction intersects the first direction; the functional region further comprises a plurality of routing lines arranged in the same one layer, wherein the plurality of routing lines comprise a plurality of first input lines, a plurality of first output lines, a plurality of second input lines, and a plurality of cascade lines.

### CROSS-REFERENCE TO RELATED APPLICATIONS

The present disclosure is a National Stage of International Application No. PCT/CN2024/098493, filed Jun. 11, 2024, which claims the priority to the Chinese patent application No. 202310960565.3, filed with China National Intellectual Property Administration on Jul. 31, 2023, the entire contents of which are incorporated by reference herein.

### TECHNICAL FIELD

The present disclosure relates to the field of display technology, and in particular to a wiring substrate, a light-emitting substrate and a display device.

### BACKGROUND

Micro light-emitting diodes are increasingly being used in the display field due to their smaller size, ultra-high brightness, and long life.

### SUMMARY

The embodiments of the present disclosure provide a wiring substrate, a light-emitting substrate and a display device to avoid poor weak brightness in the final lamp region in the cascaded lamp regions.

A wiring substrate provided by an embodiment of the present disclosure includes: a base substrate, the base substrate being divided into a functional region and a bonding region; where the functional region includes a plurality of pad units arranged along a first direction and a second direction respectively, where the pad unit includes: a first pad region, and a second pad region electrically connected to the first pad region, and the second direction intersects the first direction; the functional region further includes a plurality of routing lines arranged in the same layer, where the plurality of routing lines include a plurality of first input lines, a plurality of first output lines, a plurality of second input lines, and a plurality of cascade lines; input pads of the plurality of first pad regions arranged along the first direction are connected to the same one first input line, output pads of the plurality of first pad regions arranged along the first direction are connected to the same one first output line, two first pad regions that are adjacent to each other along the first direction are connected via the cascade line, and input ends of the plurality of second pad regions arranged along the first direction are connected to the same one second input line; and in the functional region, in the second direction, one side of one first output line is adjacent to the first input line, and another side of the one first output line is adjacent to another first output line or the second input line.

In some embodiments, each of the first pad regions includes a channel pad and an address pad, and in a plurality of cascaded first pad regions, the channel pad of the i^{th} stage first pad region and the address pad of the (i+1)^{th} stage first pad region are connected through the cascade line; where i is a positive integer.

In some embodiments, the plurality of pad units arranged along the first direction constitute a pad unit column, and the plurality of first pad regions in each pad unit column are sequentially cascaded along the first direction; the plurality of routing lines further include a plurality of feedback lines; and in at least part of the pad unit columns, the channel pad of the last stage first pad region among the plurality of cascaded first pad regions is connected to one of the feedback lines, and the feedback line is not adjacent to the first output line.

In some embodiments, a cascade direction of the plurality of first pad regions in one pad unit column is opposite to a cascade direction of the plurality of first pad regions in another pad unit column that is adjacent to the one pad unit column.

In some embodiments, the second input line and the first output line connected to the same one pad unit column are respectively on both sides of the pad unit column.

In some embodiments, 2N pad unit columns are included along the second direction; the first output line connected to the (2n−1)^{th} pad unit column is adjacent to the first output line connected to the 2n^{th} pad unit column; and the second input line connected to the 2n^{th} pad unit column is adjacent to the second input line connected to the (2n+1)^{th} pad unit column; where, N is a positive integer, and n is a positive integer not greater than N.

In some embodiments, the plurality of cascade lines include a plurality of first cascade lines and a plurality of second cascade lines; where the first cascade lines cascade the pad units in the pad unit column in sequence; and the second cascade line connects the last stage first pad region in the (2n−1)^{th} pad unit column to the first stage first pad region in the 2n^{th} pad unit column.

In some embodiments, the second cascade line includes: a first portion, a second portion, and a third portion connected in sequence; where at least a part of the first portion and at least a part of the third portion extend along the first direction, and the second portion extends along the second direction; and the first portion is connected to the channel pad of the last stage first pad region in the (2n−1)^{th} pad unit column, and the third portion is connected to the address pad of the first stage first pad region in the 2n^{th} pad unit column.

In some embodiments, in the first direction, the second portion is located on a side of the first output line away from the bonding region, the first portion is located on a side of the first output line electrically connected to the (2n−1)^{th} pad unit column away from the bonding region, and the third portion is located on a side of the first output line electrically connected to the 2n^{th} pad unit column away from the bonding region; and the first output line electrically connected to the (2n−1)^{th} pad unit column is not adjacent to the first portion, and the first output line electrically connected to the 2n^{th} pad unit column is not adjacent to the third portion.

In some embodiments, 2N pad unit columns are included along the second direction; where the plurality of routing lines further include a plurality of address lines and a plurality of transfer lines, the address line is connected to the address pad of the first stage first pad region in the pad unit column, and the channel pad of the last stage first pad region in the pad unit column is connected to the feedback line; the plurality of transfer lines include a plurality of first transfer lines and a plurality of second transfer lines; the first transfer line electrically connects the feedback line connected to the (2n−1)^{th} pad unit column to the address line connected to the 2n^{th} pad unit column; and the second transfer line electrically connects the feedback line connected to the 2n^{th} pad unit column to the address line connected to the (2n+1)^{th} pad unit column; where, N is a positive integer, and n is a positive integer not greater than N.

In some embodiments, the feedback line connected to the (2n−1)^{th} pad unit column is located on a side of the first output line connected to the (2n−1)^{th} pad unit column away from the bonding region; the first transfer line includes: a fourth portion extending along the second direction, and a fifth portion extending along the first direction in the functional region; where the feedback line connected to the (2n−1)^{th} pad unit column is connected to one end of the fourth portion, and the fifth portion is connected to another end of the fourth portion; and the second input line connected to the (2n−1)^{th} pad unit column is adjacent to the fifth portion.

In some embodiments, the address line connected to the 2n^{th} pad unit column is located on a side of the first output line connected to the 2n^{th} pad unit column away from the bonding region; the second transfer line includes: a sixth portion extending along the second direction, and a seventh portion extending along the first direction in the functional region; where the address line connected to the 2n^{th} pad unit column is connected to one end of the sixth portion, and the seventh portion is connected to another end of the sixth portion; and the second input line connected to the 2n^{th} pad unit column is adjacent to the seventh portion.

In some embodiments, the fifth portion is adjacent to the seventh portion in a region between the second input line connected to the 2n^{th} pad unit column and the second input line connected to the (2n−1)^{th} pad unit column.

In some embodiments, the first pad region includes the address pad, the input pad, the channel pad and the output pad; the address pad and the input pad are located in the same one row in the first direction, and the channel pad and the output pad are located in the same one row in the first direction; and the channel pad and the address pad are located in the same one column in the second direction, and the output pad and the input pad are located in the same one column in the second direction; and in the (2n−1)^{th} pad unit column, the address pads and the input pads are located on a side of the channel pads and the output pads close to the bonding region in the first direction; and the first pad region in the 2n^{th} pad unit column after being rotated 180° is arranged in the same manner as the first pad region in the (2n−1)^{th} pad unit column; where N is a positive integer and n is a positive integer not greater than N.

In some embodiments, among the address line, the first input line, and the first output line electrically connected to the (2n−1)^{th} pad unit column, the first input line is located between the address line and the first output line in the second direction; among the feedback line, the first input line, and the first output line corresponding to the 2n^{th} pad unit column, the first input line is located between the feedback line and the first output line in the second direction.

In some embodiments, the second pad region has a median line extending along the first direction; the first pad region in the (2n−1)^{th} pad unit column is located on a side of the median line facing the 2n^{th} pad unit column, and the first pad region in the 2n^{th} pad unit column is located on a side of the median line facing the (2n−1)^{th} pad unit column.

An embodiment of the present disclosure provides a light-emitting substrate, including: the wiring substrate provided in the embodiment of the present disclosure, driving elements bonded one-to-one with the first pad regions, and light-emitting elements bonded one-to-one with a plurality of pad groups in the second pad regions.

In some embodiments, the light-emitting substrate further includes: a circuit board bonded to the wiring substrate in the bonding region; where the circuit board includes a plurality of first circuit structures and a plurality of second circuit structures; and the wiring substrate includes: pad unit columns, first transfer lines, second transfer lines, address lines, and feedback lines; the first transfer line corresponding to the (2n−1)^{th} pad unit column is electrically connected to the address line connected to the 2n^{th} pad unit column through the first circuit structure; and the second transfer line corresponding to the 2n^{th} pad unit column is electrically connected to the feedback line connected to the 2n^{th} pad unit column through the second circuit structure.

In some embodiments, the light-emitting element is a micro-sized inorganic light-emitting diode.

A display device provided by an embodiment of the present disclosure includes the light-emitting substrate provided by the embodiment of the present disclosure.

### BRIEF DESCRIPTION OF FIGURES

FIG. 1 is a schematic structural diagram of a light-emitting substrate provided by the related art.

FIG. 2 is a schematic diagram of a feedback line FB and a first output line GND of a light-emitting substrate that are adjacent to each other and form a weak conduction in the related art.

FIG. 3 is a schematic structural diagram of a wiring substrate provided in an embodiment of the present disclosure.

FIG. 4 is an enlarged schematic structural diagram of a region A in FIG. 3.

FIG. 5 is a schematic structural diagram of another wiring substrate provided in an embodiment of the present disclosure.

FIG. 6 is an enlarged schematic structural diagram of a region C in FIG. 5.

FIG. 7 is a schematic structural diagram of another wiring substrate provided in an embodiment of the present disclosure.

FIG. 8 is an enlarged schematic structural diagram of a region D in FIG. 7.

FIG. 9 is a schematic structural diagram of a light-emitting substrate provided in an embodiment of the present disclosure.

FIG. 10 is a schematic structural diagram of another light-emitting substrate provided in an embodiment of the present disclosure.

FIG. 11 is a schematic structural diagram of a display device provided in an embodiment of the present disclosure.

### DETAILED DESCRIPTION

In order to make the purpose, technical solution and advantages of the embodiments of the present disclosure clearer, the technical solution of the embodiments of the present disclosure will be clearly and completely described below in conjunction with the drawings of the embodiments of the present disclosure. Obviously, the described embodiments are part of the embodiments of the present disclosure, not all of the embodiments. Additionally, in the absence of conflict, the embodiments in the present disclosure and the features in the embodiments can be combined with each other. Based on the described embodiments of the present disclosure, all other embodiments obtained by ordinary technicians in the field without creative work are within the clamed scope of the present disclosure.

Unless otherwise defined, the technical terms or scientific terms used in the present disclosure should be understood by people with ordinary skills in the field to which the present disclosure belongs. “First”, “second” and similar words used in the present disclosure do not indicate any order, quantity or importance, but are only used to distinguish different components. “Include” or “comprise” and similar words mean that the elements or objects appearing before the word cover the elements or objects listed after the word and their equivalents, without excluding other elements or objects. “Connect” or “couple” and similar words are not limited to physical or mechanical connections, but may include electrical connections, whether direct or indirect.

It should be noted that the sizes and shapes of the figures in the accompanying drawings do not reflect the actual proportions, and are only intended to illustrate the present disclosure. The same or similar reference numerals throughout represent the same or similar elements or elements having the same or similar functions.

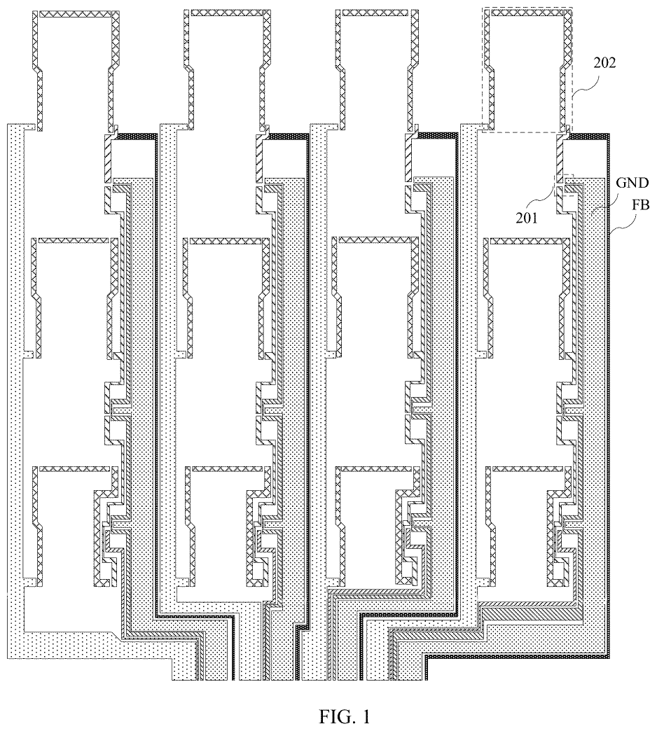

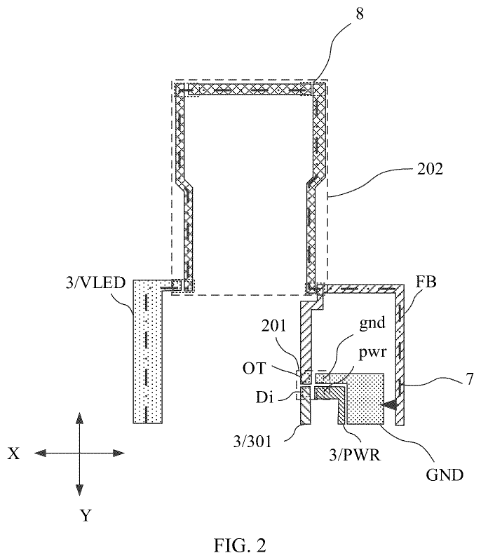

In the related art, a column of lamp regions of the light-emitting substrate constitutes an address loop, that is, a plurality of lamp regions in a column of lamp regions are cascaded, and each lamp region includes a first pad region and a second pad region, the first pad region is bonded to the driving element, and the second pad region is bonded to the light-emitting device. As shown in FIG. 1, the first output line GND is connected to the output pad gnd of the first pad region 201, the first pad region 201 and the second pad region 202 of the cascaded final lamp region are connected to the feedback line FB, and the feedback line FB and the first output line GND are arranged in the same one layer. Usually, an insulating layer is arranged between the feedback line FB and the first output line GND to insulate the feedback line FB from the first output line GND. However, since the feedback line FB is adjacent to the first output line GND and the distance between the two is very short, when the insulation resistance between the feedback line FB and the first output line GND is less than 109 ohms (Ω), the feedback line FB and the first output line GND will be weakly conductive with each other. When the second input line VLED is provided with voltage through the input end of the second pad region, but the driving element is not provided with voltage, the light-emitting device will not emit light under normal circumstances. However, for the cascaded final lamp region, the feedback line FB is adjacent to the first output line GND and forms a weak conduction with the first output line GND. The second input line VLED, the second pad region 202, the light-emitting device 8, the feedback line FB, and the first output line GND will form a conduction, i.e., the path shown by the dotted line 7 in FIG. 2. Additionally, the conduction current can reach the lighting current of the light-emitting device, so the light-emitting device in the cascaded final lamp region emits light, and although the light brightness is low, it can still be perceived, that is, the light-emitting substrate has a phenomenon of poor weak brightness in the final lamp region, which affects the display effect and user experience.

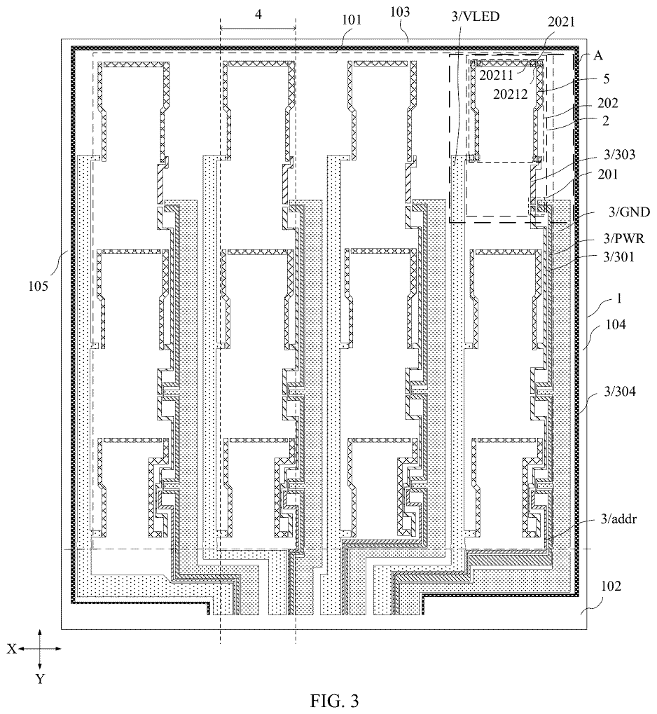

The embodiments of the present disclosure provide a wiring substrate, as shown in FIG. 3 to FIG. 8, including a base substrate 1, the base substrate 1 being divided into a functional region 101 and a bonding region 102.

The functional region 101 includes a plurality of pad units 2 arranged along a first direction Y and a second direction X, respectively. The pad unit 2 includes: a first pad region 201, and a second pad region 202 electrically connected to the first pad region 201; and the second direction X intersects the first direction Y.

The functional region 101 further includes a plurality of routing lines 3 arranged in the same layer, the plurality of routing lines 3 includes a plurality of first input lines PWR, a plurality of first output lines GND, a plurality of second input lines VLED and a plurality of cascade lines 301.

Input pads pwr of the plurality of first pad regions 201 arranged along the first direction Y are connected to the same first input line PWR, output pads gnd of the plurality of first pad regions 201 arranged along the first direction Y are connected to the same first output line GND, two first pad regions 201 that are adjacent to each other along the first direction Y are connected via the cascade line 301, and input ends of the plurality of second pad regions 202 arranged along the first direction Y are connected to the same second input line VLED.

In the functional region 101, in the second direction X, one side of the first output line GND is adjacent to the first input line PWR, and another side of the first output line GND is adjacent to another first output line GND or the second input line VLED.

It should be noted that the wiring substrate provided in the embodiment of the present disclosure can be applied to a light-emitting substrate, each second pad region includes at least one pad group, each pad group includes a positive pad and a negative pad, each pad group is bonded to a light-emitting device, and the first pad region includes a plurality of pads, and the plurality of pads are bonded to a driver chip, so that the light-emitting device can be driven to emit light under the control of the driver chip. For example, a driver chip can control each light-emitting device in a second pad region corresponding to the driver chip to emit light. A region occupied by the plurality of pads bonded to a driver chip is the first pad region, and the pad group corresponding to the light-emitting device controlled by a driver chip and the region surrounded by it are the second pad region.

In the wiring substrate provided by the embodiments of the present disclosure, one side of the first output line is adjacent to the first input line PWR, and another side thereof is adjacent to another first output line or the second input line, that is, the first output line is not adjacent to the feedback line. Therefore, when the wiring substrate is applied to the light-emitting substrate, it can avoid the weak conduction between the feedback line and the first output line, which causes the conduction formed among the light-emitting device, the pad group, the feedback line and the first output line, thereby avoiding the light-emitting device from being lit, and avoiding the phenomenon of poor weak brightness of the light-emitting region corresponding to the cascaded final second pad region, thereby improving the display effect and enhancing user experience.

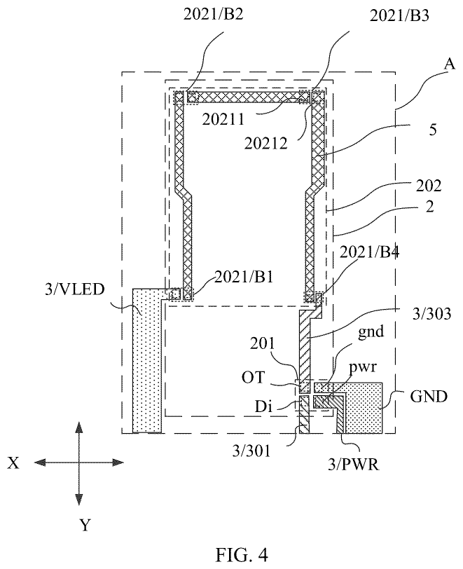

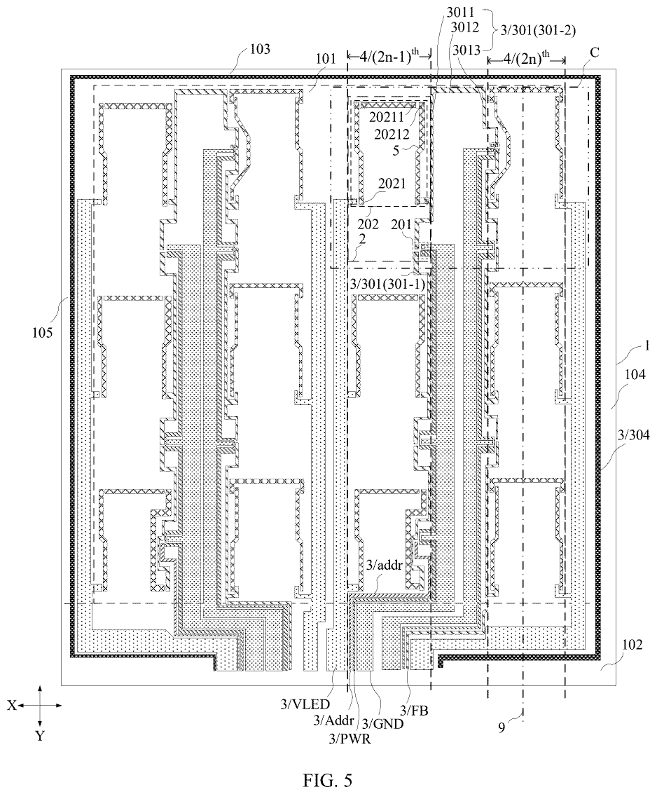

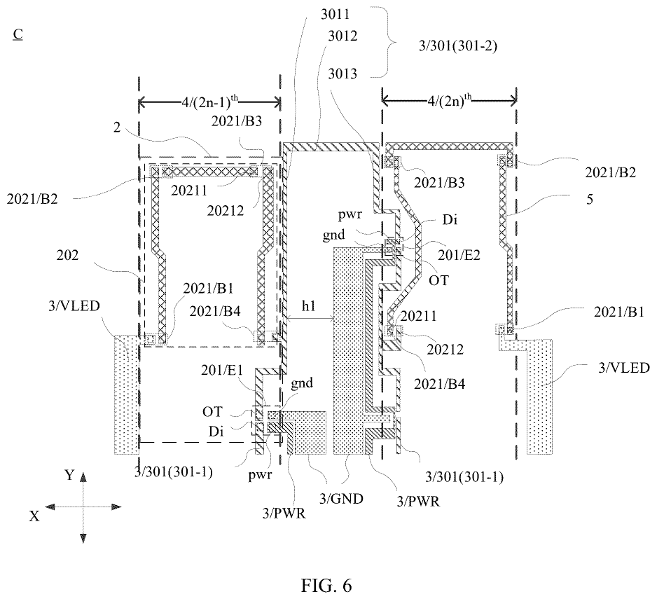

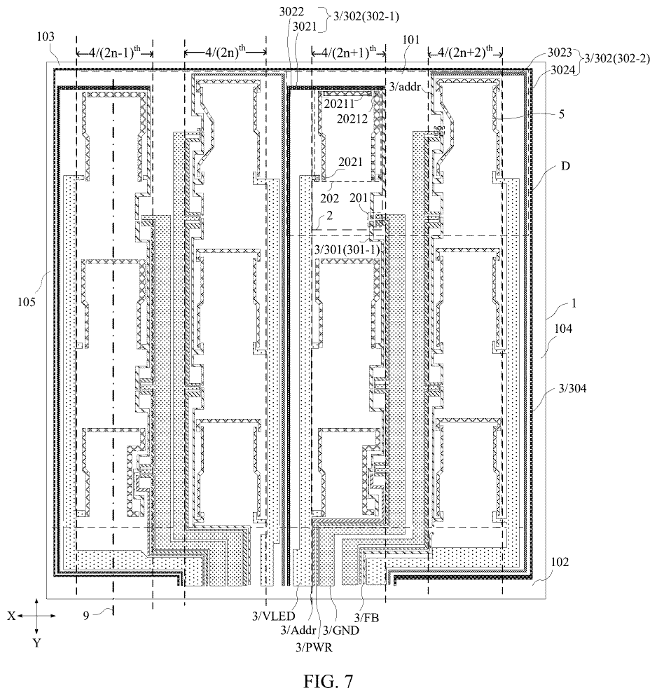

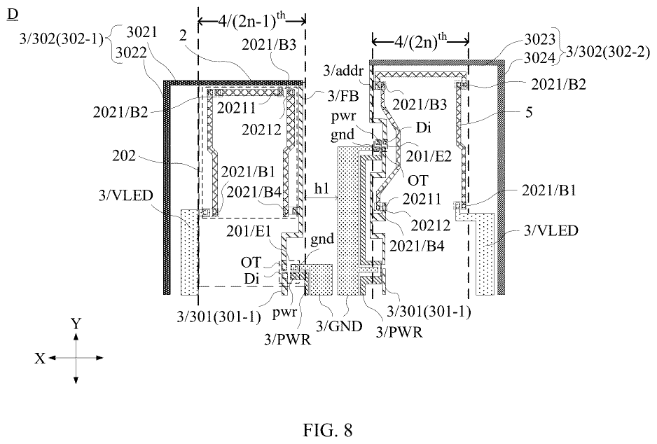

It should be noted that FIG. 4 is an enlarged schematic diagram of a region A in FIG. 3, FIG. 6 is an enlarged schematic diagram of a region C in FIG. 5, and FIG. 8 is an enlarged schematic diagram of a region D in FIG. 7.

In some embodiments, as shown in FIG. 3 and FIG. 4, the second pad region 202 includes a plurality of pad groups 2021; for example, a plurality of pad groups 2021 are connected in series; each pad group 2021 includes a positive pad 20211 and a negative pad 20212. In two connected pad groups 2021, the positive pad 20211 of one pad group 2021 is connected to the negative pad 20212 of another pad group 2021. FIG. 3 to FIG. 8 take the example that the second pad region 202 includes four pad groups 2021 connected in series as an example for illustration. As shown in FIG. 4, FIG. 6, and FIG. 8, the four pad groups 2021 are B1, B2, B3, and B4, respectively. The negative pad 20212 of the B1 pad group 2021 is connected to the positive pad 20211 of the B2 pad group 2021, the negative pad 20212 of the B2 pad group 2021 is connected to the positive pad 20211 of the B3 pad group 2021, and the negative pad 20212 of the B3 pad group 2021 is connected to the positive pad 20211 of the B4 pad group 2021.

It should be noted that the input end of the second pad region refers to the positive pad of one of the pad groups included in the second pad region. As shown in FIGS. 3 to 8, when the plurality of pad groups 2021 included in the second pad region 202 are connected in series, the positive pad 20211 of the first second pad group 2021, i.e., the B1 pad group 2021 in FIG. 4, in the plurality of second pad groups 2021 connected in series, is connected to the second input line VLED, and the negative pad 20212 of the last second pad group 2021, i.e., the B4 pad group 2021 in FIGS. 4, 6, and 8, in the plurality of second pad groups 2021 in series, is connected to the first pad region 201.

Of course, in specific implementation, the plurality of pad groups can also be connected in parallel.

In some embodiments, as shown in FIG. 3, FIG. 5, and FIG. 7, the plurality of pad units 2 arranged along the first direction Y constitute a pad unit column 4, and the plurality of first pad regions 201 in each pad unit column 4 are sequentially cascaded along the first direction Y.

It should be noted that only four pad unit columns 4 are shown for illustration in FIGS. 3, 5 and 7. In a specific implementation, the number of pad unit columns included in the wiring substrate can be set according to actual needs.

In some embodiments, as shown in FIGS. 3 to 5, each first pad region 201 includes a channel pad OT and an address pad Di, and in a plurality of cascaded first pad regions 201, and the channel pad OT of the i^{th} stage first pad region 201 and the address pad Di of the (i+1)^{th} stage first pad region 201 are connected through the cascade line 301; where i is a positive integer.

In a specific implementation, the bonding region further includes a bonding pad(s) electrically connected to at least part of the routing lines; and the bonding pad is used for bonding to the circuit board.

It should be noted that the plurality of first pad regions cascaded by cascade lines constitute an addressing loop. In a specific implementation, at least one pad unit column constitutes an addressing loop. In the related art, the first stage first pad region of each pad unit column is connected to the address line, and the channel pad of the last stage first pad region of each pad unit column is connected to the feedback line, and the address line and the feedback line are electrically connected to the bonding pad, so that different address lines and/or feedback lines can be electrically connected through a circuit board, so that multiple columns of first pad groups are cascaded through feedback lines and circuit boards, so that the cascaded multiple columns of first pad groups constitute an addressing loop. Usually, the last stage first pad region of each pad unit column is the first pad region farthest from the bonding region in the pad unit column. In order to facilitate wiring, the feedback line extends to pass through the region between the first output line and the second input line into the bonding region and is electrically connected to the bonding pad, so the feedback line needs to be adjacent to the first output line.

In some embodiments, as shown in FIG. 3, the plurality of cascaded first pad regions 201 in each pad unit column 4 constitute an addressing loop, and different pad unit columns 4 constitute different addressing loops.

That is, in some embodiments, as shown in FIG. 3 and FIG. 4, the wiring substrate does not include the feedback lines. In FIG. 3, among the plurality of first pad regions 201 cascaded by the cascade lines 301, the channel pad OT of the last stage first pad region 201 is connected to the negative pad 20212 of the last second pad group 2021, i.e., the B4 pad group 2021 in FIG. 4, of the plurality of second pad groups 2021 connected in series only through the second output line 303.

Therefore, as shown in FIG. 3, in the functional region 101, in the second direction X, one side of the first output line GND is adjacent to the first input line PWR, and another side of the first output line GND is adjacent to the second input line VLED.

It should be noted that, as shown in FIG. 3, the base substrate 1 further includes: a first frame region 103 located in the functional region 101 away from the bonding region 102 in the first direction Y, and a second frame region 104 and a third frame region 105 respectively located on both sides of the functional region in the second direction X. Among the plurality of pad unit columns 4 arranged in the second direction X, the second input line VLED of the first pad unit column 4 is located in the third frame region 105, and the first output line GND of the last pad unit column 4 is located in the second frame region 104.

In some embodiments, as shown in FIG. 3, the routing lines 3 further includes an electrostatic shielding line 304, which extends from one side of the bonding region 102 to the third frame region 105, the first frame region 103, the second frame region 104 and then returns to another side of the bonding region 102. In the third frame region 105, the second input line VLED is adjacent to the electrostatic shielding line 304, and the electrostatic shielding line 304 is located on a side of the second input line VLED away from the functional region 101. In the second frame region 104, the first output line GND is adjacent to the electrostatic shielding line 304, and the electrostatic shielding line 304 is located on a side of the first output line GND away from the functional region 101.

That is, in the wiring substrate provided in the embodiments of the present disclosure, the feedback lines are removed, so that without changing the layout of the pad units and routing lines of the wiring substrate, the light-emitting device being lit because of the conduction among the light-emitting device, the pad group, the feedback line and the first output line due to the weak conduction between the feedback line and the first output line can be avoided, and the phenomenon of poor weak brightness of the light-emitting region corresponding to the cascaded final second pad region is avoided, thereby improving the display effect and enhancing the user experience.

Alternatively, in some embodiments, the plurality of pad unit columns constitute an addressing loop.

In some embodiments, as shown in FIG. 5 and FIG. 7, the plurality of routing lines 3 further include a plurality of feedback lines FB.

In at least part of the pad unit columns, the channel pad OT of the last stage first pad region 201 of the plurality of cascaded first pad regions 201 is connected to a feedback line FB, and the feedback line FB is not disposed adjacent to the first output line GND.

In the wiring substrate provided by the embodiment of the present disclosure, in at least part of the pad unit columns, the channel pad of the last stage first pad region in the plurality of cascaded first pad regions is connected to a feedback line, so that different pad unit columns can be cascaded through the feedback lines. In addition, since the feedback line is not adjacent to the first output line, even if the feedback line is set, it will not cause weak conduction between the feedback line and the first output line. Therefore, the light-emitting device being lit because of the conduction among the light-emitting device, the pad group, the feedback line and the first output line will not appear, and the phenomenon of poor weak brightness of the light-emitting region corresponding to the cascaded final second pad region is avoided, thereby improving the display effect and enhancing the user experience.

In some embodiments, as shown in FIG. 5 and FIG. 7, the plurality of routing lines 3 further include a plurality of address lines addr.

In at least part of the pad unit columns, the address pad Di of the first stage first pad region 201 of the plurality of cascaded first pad regions 201 is connected to an address line addr.

In some embodiments, as shown in FIG. 5 and FIG. 7, in adjacent pad unit columns 4, a cascade direction of the plurality of first pad regions 201 in one pad unit column 4 is opposite to a cascade direction of the plurality of first pad regions in another pad unit column that is adjacent to the one pad unit column.

This facilitates the cascading between two adjacent pad unit columns. In addition, since the cascade directions of the plurality of first pad regions in the adjacent pad unit columns are opposite, the final first pad regions of some pad unit columns can be set to be located in the region closest to the bonding region in the pad unit columns, so that the feedback lines connected to the final first pad regions of some pad unit columns extend directly from the functional region to the bonding region without extending to the bonding region by passing through the region between the adjacent pad unit columns, so that the feedback line FB does not need to be adjacent to the first output line GND. The light-emitting device being lit because of the conduction among the light-emitting device, the pad group, the feedback line and the first output line due to the weak conduction between the feedback line and the first output line can be avoided, and the phenomenon of poor weak brightness of the light-emitting region corresponding to the cascaded final second pad region is avoided, thereby improving the display effect and enhancing the user experience.

In specific implementation, as shown in FIGS. 5 and 7, in an odd-numbered pad unit column 4, the first stage first pad region 201 is the first pad region 201 in the pad unit column 4 that is closest to the bonding region 102, and the last stage first pad region 201 is the first pad region 201 in the pad unit column 4 that is farthest from the bonding region 102; and in an even-numbered pad unit column 4, the first stage first pad region 201 is the first pad region 201 in the pad unit column 4 that is farthest from the bonding region 102, and the last stage first pad region 201 is the first pad region 201 in the pad unit column 4 that is close to the bonding region 102.

In some embodiments, as shown in FIG. 5 and FIG. 7, the second input line VLED and the first output line GND connected to the same one pad unit column 4 are respectively located at two sides of this pad unit column 4.

In some embodiments, 2N pad unit columns are included along the second direction X.

In some embodiments, as shown in FIG. 6 and FIG. 8, the first pad region 201 includes an address pad Di, an input pad pwr, a channel pad OT, and an output pad gnd.

The address pad Di and the input pad pwr are located in the same row in the first direction Y, and the channel pad OT and the output pad gnd are located in the same row in the first direction Y; and the channel pad OT and the address pad Di are located in the same column in the second direction X, and the output pad gnd and the input pad pwr are located in the same column in the second direction X.

In the (2n−1)^{th} pad unit column 4, the address pads Di and the input pads pwr are located on a side of the channel pads OT and the output pads gnd close to the bonding region 102 in the first direction Y; and the first pad region 201 in the 2n^{th} pad unit column 4 after being rotated 180° is arranged in the same arrangement as the first pad region 201 in the (2n−1)^{th} pad unit column 4; where N is a positive integer and n is a positive integer not greater than N.

That is, in the wiring substrate provided by the embodiment of the present disclosure, the arrangement sequence of pads in the first pad regions of the odd-numbered pad unit column is different from the arrangement of pads in the first pad regions of the even-numbered pad unit column, and accordingly, the positions of routing lines corresponding to the even-numbered column are different from the positions of routing lines corresponding to the odd-numbered column. Compared with the prior art, in the embodiment of the present disclosure, the arrangement positions of the routing lines of the wiring substrate can be changed by changing the arrangement of pads in the first pad regions of the even-numbered pad unit column, so that the feedback line is not adjacent to the first output line.

In some embodiments, as shown in FIG. 5 and FIG. 7, the second pad region 202 has a median line 9 extending along the first direction Y. It can be understood that the second pad region 202 includes the plurality of pad groups 2021, and a closed pattern can be obtained by sequentially connecting geometric centers of the plurality of pad groups 2021 located at the edge of the second pad region 202, and the median line 9 can divide an area of the closed pattern into two, or the median line 9 coincides with a symmetry axis of the closed pattern, or the second pad region 202 is divided into two sub-regions with the median line 9 as the boundary, and the number of pad groups 2021 included in the two sub-regions are the same.

The first pad region 201 in the (2n−1)^{th} pad unit column 4 is located on a side of the median line 9 facing the 2n^{th} pad unit column 4, and the first pad region 201 in the 2n^{th} pad unit column 4 is located on a side of the median line 9 facing the (2n−1)^{th} pad unit column 4. That is, the first pad region 201 in the (2n−1)^{th} pad unit column 4 is located at the edge of the (2n−1)^{th} pad unit column 4 close to the 2n^{th} pad unit column 4, and the first pad region 201 in the 2n^{th} pad unit column 4 is located at the edge of the 2n^{th} pad unit column 4 close to the (2n−1)^{th} pad unit column 4. The first pad region 201 of the odd-numbered column is located on the left side of the median line 9, and the first pad region 201 of the even-numbered column is located on the right side of the median line 9.

In some embodiments, as shown in FIG. 5 and FIG. 7, the first output line GND connected to the (2n−1)^{th} pad unit column 4 is adjacent to the first output line GND connected to the 2n^{th} pad unit column 4.

The second input line VLED connected to the 2n^{th} pad unit column 4 and the second input line VLED connected to the (2n+1)^{th} pad unit column 4 are oppositely arranged between the 2n^{th} pad unit column 4 and the (2n+1)^{th} pad unit column 4.

N is a positive integer, and n is a positive integer not greater than N.

In the wiring substrate provided by the embodiment of the present disclosure, the arrangement sequence of pads in the first pad region of the odd-numbered pad unit column is different from the arrangement of pads in the first pad region of the even-numbered pad unit column, and the arrangement of the first pad region in the even-numbered pad unit column after being rotated 180° is the same as that of the first pad region in the odd-numbered pad unit column.

The first pad region in the odd-numbered pad unit column is located at the left edge of the pad unit column, and the first pad region in the even-numbered pad unit column is located at the right edge of the pad unit column, and accordingly, the first output line GND connected to the odd-numbered pad unit column is located on the right side of this pad unit column, the second input line VLED connected to the odd-numbered pad unit column is located on the left side of this pad unit column, the first output line GND connected to the even-numbered pad unit column is located on the left side of this pad unit column, and the second input line VLED connected to the even-numbered pad unit column is located on the right side of this pad unit column. Thus, between the (2n−1)^{th} pad unit column and the 2n^{th} pad unit column, the first output line GND connected to the (2n−1)^{th} pad unit column and the first output line GND connected to the 2n^{th} pad unit column are adjacent to each other; and the second input line VLED connected to the 2n^{th} pad unit column and the second input line VLED connected to the (2n+1)^{th} pad unit column are oppositely arranged between the 2n^{th} pad unit column and the (2n+1)^{th} pad unit column. Compared with the prior art, in the embodiment of the present disclosure, the arrangement positions of the routing lines of the wiring substrate can be changed by changing the arrangement of pads in the first pad regions of the even-numbered pad unit column, so that the first output line GND connected to the (2n−1)^{th} pad unit column is adjacent to the first output line GND connected to the 2n^{th} pad unit column, and the first output line is not adjacent to the feedback line, avoiding the weak conduction between the feedback line and the first output line. Therefore, the light-emitting device being lit because of the conduction among the light-emitting device, the pad group, the feedback line and the first output line will not appear, and the phenomenon of poor weak brightness of the light-emitting region corresponding to the cascaded final second pad region is avoided, thereby improving the display effect and enhancing the user experience.

In some embodiments, as shown in FIGS. 6 and 8, the address pad Di and the input pad pwr are located in the same row in the first direction Y, and in the odd-numbered pad unit column 4, the address pad Di is located on the left side of the input pad pwr, and in the even-numbered pad unit column 4, the address pad Di is located on the right side of the input pad pwr; the channel pad OT and the output pad gnd are located in the same row in the first direction Y, and in the odd-numbered pad unit column 4, the channel pad OT is located on the left side of the output pad gnd, and in the even-numbered pad unit column 4, the channel pad OT is located on the right side of the output pad gnd; the channel pad OT and the address pad Di are located in the same column in the second direction X, and in the odd-numbered pad unit column 4, the channel pad OT is located on the side of the address pad Di away from the bonding region (not shown in FIGS. 6 and 8), and in the even-numbered pad unit column 4, the channel pad OT is located on the side of the address pad Di facing the bonding region; and the output pad gnd and the input pad pwr are located in the same column in the second direction X, and in the odd-numbered pad unit column 4, the output pad gnd is located on the side of the input pad pwr away from the bonding region, and in the even-numbered pad unit column 4, the output pad gnd is located on the side of the input pad pwr facing the bonding region. The first output line GND is connected to the output pad gnd, the first input line PWR is connected to the input pad pwr, the channel pad OT of the i^{th} stage first pad region 201 is connected to the address pad Di of the (i+1)^{th} stage first pad region 201 through the cascade line 301.

Accordingly, in some embodiments, as shown in FIGS. 5 and 7, among the address line addr, the first input line PWR and the first output line GND electrically connected to the (2n−1)^{th} pad unit column 4, in the second direction X, the first input line PWR is located between the address line addr and the first output line GND; and among the feedback line FB, the first input line PWR and the first output line GND corresponding to the 2n^{th} pad unit column 4, in the second direction X, the first input line PWR is located between the feedback line FB and the first output line GND. In the second direction X, the cascade line 301 corresponding to the (2n−1)^{th} pad unit column is located on the side of the first output line GND electrically connected to the (2n−1)^{th} pad unit column away from the 2n^{th} pad unit column, and the first input line PWR is located between the cascade line 301 and the first output line GND, that is, in the odd-numbered pad unit column 4, the first input line PWR is located on the left side of the first output line GND, and the cascade line 301 is located on the left side of the first input line PWR; and the cascade line 301 corresponding to the 2n^{th} pad unit column is located on the side of the first output line GND electrically connected to the 2n^{th} pad unit column away from the (2n−1)^{th} pad unit column, and the first input line PWR is located between the cascade line 301 and the first output line GND, that is, in the even-numbered pad unit column 4, the first input line PWR is located on the right side of the first output line GND, and the cascade line 301 is located on the right side of the first input line PWR.

In some embodiments, 2N pad unit columns include M addressing loops, M is a positive integer greater than 1 and less than or equal to N, and 2N/M is a positive integer greater than 1. That is, 2N/M pad unit columns constitute an addressing loop. In one addressing loop, different pad unit columns are cascaded, that is, all first pad regions in 2N/M pad unit columns are cascaded.

In some embodiments, as shown in FIG. 5, the address pad Di of the first stage first pad region 201 in the plurality of cascaded first pad regions 201 is connected to the address line addr, and the channel pad OT of the last stage first pad region 201 in the plurality of cascaded first pad regions 201 is connected to the feedback line FB.

In some embodiments, for the wiring substrate shown in FIG. 5, for example, M=N, that is, 2N pad unit columns 4 constitute N addressing loops, and two pad unit columns constitute one addressing loop.

In some embodiments, as shown in FIG. 5 and FIG. 6, the (2n−1)^{th} pad unit column 4 is cascaded with the 2n^{th} pad unit column 4. The first stage first pad region 201 in the (2n−1)^{th} pad unit column 4 is the first stage first pad region 201 in the plurality of cascaded first pad regions 201, and the last stage first pad region 201 in the 2n^{th} pad unit column 4 is the last stage first pad region 201 in the plurality of cascaded first pad regions 201. That is, the address pad Di of the first stage first pad region 201 in the (2n−1)^{th} pad unit column 4 is connected to an address line addr, and the channel pad OT of the last stage first pad region 201 in the 2n^{th} pad unit column 4 is connected to a feedback line FB.

In a specific implementation, as shown in FIG. 5, the first stage first pad region 201 in the (2n−1)^{th} pad unit column 4 is the first pad region 201 in the (2n−1)^{th} pad unit column 4 that is closest to the bonding region 102, and the address line addr connected to the address pad Di of the first stage first pad region 201 in the (2n−1)^{th} pad unit column 4 extends directly from the functional region 101 to the bonding region 102, the address line addr is adjacent to the first input line PWR, and the address line addr is located on the side of the first input line PWR away from the first output line GND, that is, the address line addr is located on the left side of the first input line PWR. The last stage first pad region 201 in the 2n^{th} pad unit column 4 is the first pad region 201 in the 2n^{th} pad unit column 4 that is closest to the bonding region 102. The feedback line FB connected to the channel pad OT of the last stage first pad region 201 in the 2n^{th} pad unit column 4 extends directly from the functional region 101 to the bonding region 102. The feedback line FB is adjacent to the first input line PWR, and the feedback line FB is located on the side of the first input line PWR that is away from the first output line GND, that is, the feedback line FB is located on the right side of the first input line PWR.

In some embodiments, as shown in FIG. 5, the plurality of cascade lines 301 include a plurality of first cascade lines 301-1 and a plurality of second cascade lines 301-2.

The first cascade lines 301-1 cascade the pad units 2 in the pad unit column 4 in sequence.

The second cascade line 301-2 connects the last stage first pad region 201 in the (2n−1)^{th} pad unit column 4 to the first stage first pad region 201 in the 2n^{th} pad unit column 4.

In the wiring substrate provided by the embodiment of the present disclosure, the (2n−1)^{th} pad unit column and the 2n^{th} pad unit column are connected by the second cascade line, so that the (2n−1)^{th} pad unit column and the 2n^{th} pad unit column are cascaded to form an addressing loop.

In some embodiments, as shown in FIGS. 5 and 6, the last stage first pad region 201 (the first pad region 201 marked as E1 in FIG. 6) in the (2n−1)^{th} pad unit column 4 is the first pad region 201 in the (2n−1)^{th} pad unit column 4 farthest from the bonding region 102; the first stage first pad region 201 (the first pad region 201 marked as E2 in FIG. 6) in the 2n^{th} pad unit column 4 is the first pad region 201 in the 2n^{th} pad unit column 4 farthest from the bonding region 102; and the second cascade line 301-2 connects the first pad region 201 marked as E1 and the first pad region 201 marked as E2. That is, in the first direction Y, the second cascade line 301-2 is closer to the second frame region 103, and the second cascade line 301-2 is located at the edge of the functional region 101 away from the bonding region 101. The second cascade line 301-2 connects the last stage first pad region 201 (the first pad region 201 marked as E1 in FIG. 6) in the (2n−1)^{th} pad unit column 4 with the first stage first pad region 201 (the first pad region 201 marked as E2 in FIG. 6) in the 2n^{th} pad unit column 4 in the region away from the bonding region 102.

In the wiring substrate provided by the embodiment of the present disclosure, the arrangement positions of pads in the first pad regions in the even-numbered pad unit column are designed, so that the arrangement positions of pads in the first pad regions in the even-numbered pad unit column are different from the arrangement positions of pads in the first pad regions in the odd-numbered pad unit column, and accordingly, the positions of routing lines corresponding to the even-numbered column are different from the positions of routing lines corresponding to the odd-numbered column. In addition, since the cascade directions of the plurality of first pad regions in adjacent pad unit columns are opposite, it can be set that, in an addressing loop, the first stage and last stage first pad regions of the plurality of cascaded first pad regions are both in the region closest to the bonding region in the pad unit column, so that the feedback line connected to the final first pad region extends directly from the functional region to the bonding region without passing through the region between adjacent pad unit columns to extend to the bonding region, so that the feedback line FB does not need to be adjacent to the first output line GND. Since the cascade directions of the plurality of first pad regions in adjacent pad unit columns are opposite, the first pad region in the (2n−1)^{th} pad unit column and the first pad region in the 2n^{th} pad unit column that need to be cascaded are both located in the regions farthest from the bonding region in the pad unit columns. Therefore, the second cascade line is set at the edge farthest from the bonding region to achieve the cascading of the (2n−1)^{th} pad unit column and the 2n^{th} pad unit column. That is, by the routing lines provided in the embodiment of the present disclosure, the cascading of the (2n−1)^{th} pad unit column and the 2n^{th} pad unit column can be achieved without setting the feedback line FB adjacent to the first output line GND, thereby avoiding weak conduction between the feedback line and the first output line. Therefore, the light-emitting device being lit because of the conduction among the light-emitting device, the pad group, the feedback line and the first output line will not appear, and the phenomenon of poor weak brightness of the light-emitting region corresponding to the cascaded final second pad region is avoided, thereby improving the display effect and enhancing the user experience.

In some embodiments, as shown in FIG. 5 and FIG. 6, the second cascade line 301-2 includes: a first portion 3011, a second portion 3012, and a third portion 3013 that are sequentially connected.

At least a part of the first portion 3011 and at least a part of the third portion 3013 extend along the first direction Y, and the second portion 3012 extends along the second direction X.

The first portion 3011 is connected to the channel pad OT of the last stage first pad region 201 (the first pad region 201 marked as E1 in FIG. 6) in the (2n−1)^{th} pad unit column 4, and the third portion 3013 is connected to the address pad Di of the first stage first pad region 201 (the first pad region 201 marked as E2 in FIG. 6) of the 2n^{th} pad unit column 4.

In some embodiments, as shown in FIG. 5 and FIG. 6, in the first direction Y, the second portion 3012 is located on a side of the first output line GND away from the bonding region 102, the first portion 3011 is located on a side of the first output line GND electrically connected to the (2n−1)^{th} pad unit column 4 away from the bonding region 102, and the third portion 3013 is located on a side of the first output line GND electrically connected to the 2n^{th} pad unit column 4 away from the bonding region 102.

The first output line GND electrically connected to the (2n−1)^{th} pad unit column 4 is not adjacent to the first portion 3011, and the first output line GND electrically connected to the 2n^{th} pad unit column 4 is not adjacent to the third portion 3013.

In the wiring substrate provided by the embodiment of the present disclosure, as shown in FIG. 6, the first portion 3011 is connected to the channel pad OT of the last stage first pad region 201 (the first pad region 201 marked as E1 in FIG. 6) in the (2n−1)^{th} pad unit column 4, and the first portion 3011 is also connected to the negative pad 20212 of the B4 pad group 2021 in the second pad region 202. Therefore, the first output line GND electrically connected to the (2n−1)^{th} pad unit column 4 is not adjacent to the first portion 3011, which can avoid the weak conduction between the first output line GND electrically connected to the (2n−1)^{th} pad unit column 4 and the first portion 3011. The third portion 3013 is connected to the address pad Di of the first stage first pad region 201 (the first pad region 201 marked as E2 in FIG. 6) in the 2n^{th} pad unit column 4, and the third portion 3013 is also connected to the negative pad 20212 of the B4 pad group 2021 in the second pad region 202. The first output line GND electrically connected to the 2n^{th} pad unit column 4 is not adjacent to the third portion 3013, which can avoid the weak conduction between the first output line GND electrically connected to the 2n^{th} pad unit column 4 and the third portion 3013. Therefore, the light-emitting device being lit because of the conduction among the light-emitting device, the pad group, the second cascade line, and the first output line will appear, and the phenomenon of poor weak brightness of the light-emitting region is avoided, thereby improving the display effect and enhancing the user experience.

It should be noted that the two lines involved in the embodiment of the present disclosure are adjacent to each other, which means that there is no other line between the two lines and the distance between the two lines in the second direction X is greater than 0 and less than a first preset value, and the first preset value is, e.g., 1 mm. In the related art, in the second direction X, the feedback line FB is adjacent to the first output line GND, and the distance between the two is less than 1 mm, which is prone to weak conduction. In the wiring substrate provided by the embodiment of the present disclosure, as shown in FIGS. 5 and 6, a length of the first output line GND electrically connected to the (2n−1)^{th} pad unit column 4 in the first direction Y is less than a length of the first output line GND electrically connected to the 2n^{th} pad unit column 4 in the first direction Y. Since the first output line GND electrically connected to the (2n−1)^{th} pad unit column 4 is adjacent to the first output line GND electrically connected to the 2n^{th} pad unit column 4, in the second direction X, the first output line GND electrically connected to the 2n^{th} pad unit column 4 and the first portion 301 are oppositely arranged. However, in the second direction X, a distance h1 between the first output line GND electrically connected to the 2n^{th} pad unit column 4 and the first portion 301 is greater than 1 mm. That is, the first output line GND electrically connected to the 2n^{th} pad unit column 4 is not adjacent to the first portion 301, and since h1 is relatively large, the weak conduction between the first output line GND electrically connected to the 2n^{th} pad unit column 4 and the first portion 301 will not appear.

That is, in the wiring substrate provided in the embodiment of the present disclosure, the setting of the second cascade line will not cause weak conduction between the second cascade line and the first output line, so that the light-emitting device being lit because of the conduction among the light-emitting device, the pad group, the first portion and the first output line will not appear, and the phenomenon of poor weak brightness of the light-emitting region is avoided, thereby improving the display effect and enhancing the user experience.

In some embodiments, as shown in FIG. 5, the second input line VLED connected to the 2n^{th} pad unit column 4 is adjacent to the second input line VLED connected to the (2n+1)^{th} pad unit column 4.

In some embodiments, as shown in FIG. 5, the second input line VLED connected to the first pad unit column 4 includes a portion located in the third frame region 105, and the second input line VLED connected to the 2N^{th} pad unit column 4 includes a portion located in the second frame region 104; and in the second frame region 104 and the third frame region 105, the electrostatic shielding line 304 is located on a side of the second input line VLED away from the functional region 101, and the electrostatic shielding line 304 is adjacent to the second input line VLED.

It should be noted that in FIG. 5, two pad unit columns forming an addressing loop is taken as an example for illustration.

In a specific implementation, when the wiring substrate includes 2N pad unit columns, more pad unit columns may constitute an addressing loop, that is, more pad unit columns are cascaded. For the wiring substrate shown in FIG. 5, the feedback line FB connected to the 2n^{th} pad unit column 4 may be electrically connected to the address line addr connected to the (2n+1)^{th} pad unit column 4 through the circuit board, that is, more pad unit columns may be cascaded through the circuit board.

Of course, other configurations may be used to make multiple pad unit columns form an addressing loop.

In some embodiments, as shown in FIG. 7, the plurality of routing lines 3 further include a plurality of transfer lines 302, the address line addr is connected to the address pad Di of the first stage first pad region 201 in each pad unit column 4, and the channel pad OT of the last stage first pad region 201 in each pad unit column 4 is connected to a feedback line FB.

The plurality of transfer lines 302 include a plurality of first transfer lines 302-1 and a plurality of second transfer lines 302-2.

The first transfer line 302-1 electrically connects the feedback line FB connected to the (2n−1)^{th} pad unit column 4 and the address line addr connected to the 2n^{th} pad unit column 4.

The second transfer line 302-2 electrically connects the feedback line FB connected to the 2n^{th} pad unit column 4 and the address line addr connected to the (2n+1)^{th} pad unit column 4.

N is a positive integer, and n is a positive integer not greater than N.

It should be noted that the transfer line extends to the bonding region and is electrically connected to the bonding pad, and then is electrically connected to the circuit board. The first transfer line electrically connects the feedback line FB connected to the (2n−1)^{th} pad unit column to the address line addr connected to the 2n^{th} pad unit column, which means that the feedback line FB connected to the (2n−1)^{th} pad unit column is electrically connected to the address line addr connected to the 2n^{th} pad unit column through the first transfer line, the bonding pad, and the circuit board. The second transfer line electrically connects the feedback line FB connected to the 2n^{th} pad unit column to the address line addr connected to the (2n+1)^{th} pad unit column, which means that the feedback line FB connected to the 2n^{th} pad unit column is electrically connected to the address line addr connected to the (2n+1)^{th} pad unit column through the second transfer line, the bonding pad, and the circuit board.

In the wiring substrate provided in the embodiment of the present disclosure, electrical connection between more than two adjacent pad unit columns is realized through the first transfer line and the second transfer line, that is, more than two adjacent pad unit columns are cascaded to form an addressing loop.

In some embodiments, 2N pad unit columns include M′ addressing loops, M′ is a positive integer greater than 1 and less than N, and 2N/M′ is a positive integer greater than 2. That is, 2N/M′ pad unit columns constitute an addressing loop. In one addressing loop, different pad unit columns are cascaded, that is, all first pad regions in 2N/M′ pad unit columns are cascaded.

In some embodiments, for the wiring substrate shown in FIG. 7, for example, M′=N/2, that is, 2N pad unit columns 4 constitute N/2 addressing loops, and 4 pad unit columns constitute one addressing loop.

In some embodiments, as shown in FIGS. 7 and 8, the last stage first pad region 201 (the first pad region 201 marked as E1 in FIG. 8) in the odd-numbered pad unit column 4 is the first pad region 201 in the pad unit column 4 farthest from the bonding region 102; the first stage first pad region 201 (the first pad region 201 marked as E2 in FIG. 8) in the even-numbered pad unit column 4 is the first pad region 201 farthest from the bonding region 102; the address pad Di of the first stage first pad region 201 in the odd-numbered pad unit column 4 is connected to the address line addr, which directly extends to the bonding region 101, and the channel pad OT of the last stage first pad region 201 is connected to a feedback line FB, which is connected to the first transfer line 302-1; and in the even-numbered pad unit column 4, the channel pad OT of the last stage first pad region 201 is connected to a feedback line FB, which directly extends to the bonding region 101, and the address pad Di of the first stage first pad region 201 is connected to the address line addr, which is connected to the second transfer line 302-2.

In some embodiments, as shown in FIG. 7, the feedback line FB connected to the (2n−1)^{th} pad unit column 4 is located on a side of the first output line GND connected to the (2n−1)^{th} pad unit column 4 away from the bonding region 102.

Therefore, the weak conduction between the feedback line and the first output line can be avoided, and the light-emitting device being lit because of the conduction among the light-emitting device, the pad group, the feedback line, and the first output line can be avoided, and the phenomenon of poor weak brightness of the light-emitting region is avoided, thereby improving the display effect and enhancing the user experience.

In some embodiments, as shown in FIG. 7, the first transfer line 302-1 includes: a fourth portion 3021 extending along the second direction X, and a fifth portion 3022 extending along the first direction Y in the functional region 101; where the feedback line FB connected to the (2n−1)^{th} pad unit column 4 is connected to one end of the fourth portion 3021, and the fifth portion 3022 is connected to another end of the fourth portion 3021.

The second input line VLED connected to the (2n−1)^{th} pad unit column 4 is adjacent to the fifth portion 3022.

In some embodiments, the address line addr connected to the 2n^{th} pad unit column 4 is located on a side of the first output line GND connected to the 2n^{th} pad unit column 4 away from the bonding region 102.

The second transfer line 302-2 includes: a sixth portion 3023 extending along the second direction X, and a seventh portion 3024 extending along the first direction Y in the functional region 101; where the address line addr connected to the 2n^{th} pad unit column 4 is connected to one end of the sixth portion 3023, and the seventh portion 3024 is connected to another end of the sixth portion 3023.

The second input line VLED connected to the 2n^{th} pad unit column 4 is adjacent to the seventh portion 3024.

In some embodiments, the fifth portion 3022 is adjacent to the seventh portion 3024 in a region between the second input line VLED connected to the 2n^{th} pad unit column 4 and the second input line VLED connected to the (2n−1)^{th} pad unit column 4.

In some embodiments, as shown in FIG. 7, the fifth portion 3022 of the first transfer line 302-1 corresponding to the first pad unit column 4 includes a portion located in the third frame region 105, and in the third frame region 105, the fifth portion 3022 is located between the second input line VLED and the electrostatic shielding line 304. The fifth portion 3022 of the first transfer line 302-1 corresponding to the 2N^{th} pad unit column 4 includes a portion located in the second frame region 104, and in the second frame region 104, the fifth portion 3022 is located between the second input line VLED and the electrostatic shielding line 304.

In the wiring substrate provided by the embodiment of the present disclosure, the arrangement positions of pads in the first pad regions in the even-numbered pad unit column are designed, so that the arrangement positions of pads in the first pad regions in the even-numbered pad unit column are different from the arrangement positions of pads in the first pad regions in the odd-numbered pad unit column, and accordingly, the positions of routing lines corresponding to the even-numbered column are different from the positions of routing lines corresponding to the odd-numbered column. In addition, since the cascade directions of the plurality of first pad regions in adjacent pad unit columns are opposite, it can be set that, in an addressing loop, the first stage and last stage first pad regions of the plurality of cascaded first pad regions are both in the region closest to the bonding region in the pad unit column, so that the feedback line connected to the final first pad region extends directly from the functional region to the bonding region without passing through the region between adjacent pad unit columns to extend to the bonding region, so that the feedback line FB does not need to be adjacent to the first output line GND. Since the cascade directions of the plurality of first pad regions in adjacent pad unit columns are opposite, the first pad region in the (2n−1)^{th} pad unit column and the first pad region in the 2n^{th} pad unit column that need to be cascaded are both located in the regions farthest from the bonding region in the pad unit columns. Therefore, the second cascade line is set at the edge farthest from the bonding region to achieve the cascading of the (2n−1)^{th} pad unit column and the 2n^{th} pad unit column. That is, by the routing lines provided in the embodiment of the present disclosure, the cascading of the (2n−1)^{th} pad unit column and the 2n^{th} pad unit column can be achieved without setting the feedback line FB adjacent to the first output line GND, thereby avoiding weak conduction between the feedback line and the first output line. Therefore, the light-emitting device being lit because of the conduction among the light-emitting device, the pad group, the feedback line and the first output line will not appear, and the phenomenon of poor weak brightness of the light-emitting region corresponding to the cascaded final second pad region is avoided, thereby improving the display effect and enhancing the user experience.

In the wiring substrate provided by the embodiment of the present disclosure, the arrangement positions of pads in the first pad regions in the even-numbered pad unit column are designed, so that the arrangement positions of pads in the first pad regions in the even-numbered pad unit column are different from the arrangement positions of pads in the first pad regions in the odd-numbered pad unit column, and accordingly, the positions of routing lines corresponding to the even-numbered column are different from the positions of routing lines corresponding to the odd-numbered column. Between the (2n−1)^{th} pad unit column and the 2n^{th} pad unit column, the two first output lines GND are adjacent, and between the 2n^{th} pad unit column and the (2n+1)^{th} pad unit column, the two second input lines VLED are oppositely arranged. Moreover, the feedback line FB connected to the last stage first pad region in the odd-numbered pad unit column is electrically connected to the bonding terminal of the bonding region through the first transfer line extending between the two second input lines VLED, and the address line addr connected to the first stage first pad region in the even-numbered pad unit column is electrically connected to the bonding terminal of the bonding region through the second transfer line extending between the two second input lines VLED, so that the transfer line(s) of the cascaded pad unit columns is not adjacent to the first output line GND, which can avoid the weak conduction between the feedback line and the first output line. Therefore, the light-emitting device being lit because of the conduction among the light-emitting device, the pad group, the feedback line and the first output line will not appear, and the phenomenon of poor weak brightness of the light-emitting region corresponding to the cascaded final second pad region is avoided, thereby improving the display effect and enhancing the user experience.

In some embodiments, the routing line, positive pad, negative pad, address pad, channel pad, output pad, and input pad are arranged in the same layer. The routing line, positive pad, negative pad, address pad, channel pad, output pad, and input pad are made of the same material, for example, the material includes copper. In a specific implementation, a copper conductive layer can be formed on one side of the base substrate, and then the copper conductive layer is patterned to form the routing lines and the pattern of each pad.

In some embodiments, the wiring substrate further includes a first insulating layer located on the side of the routing line, positive pad, negative pad, address pad, channel pad, output pad, and input pad away from the base substrate. The first insulating layer has a plurality of openings. It can be understood that, in the patterned copper conductive layer, the portions exposed by the openings of the insulating layer are the pads, and the region covered by the insulating layer is the routing line. The electronic element and the driving element include at least two pins, and each pad is used to fix and connect with the pin of the electronic element or the driving element.

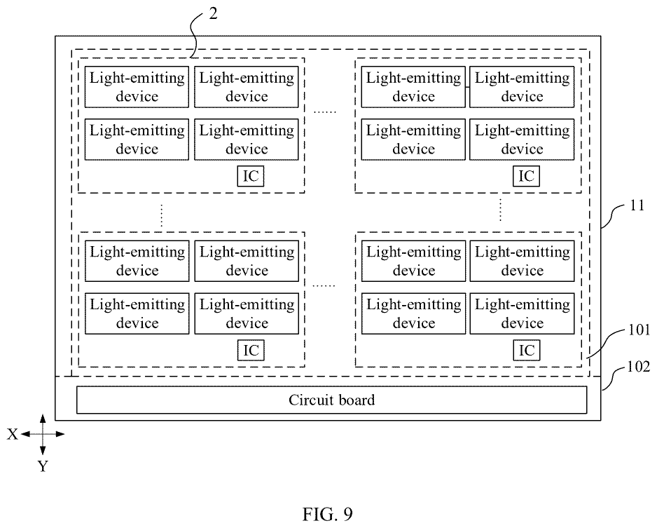

Based on the same inventive concept, the embodiment of the present disclosure further provides a light-emitting substrate, as shown in FIG. 9, the light-emitting substrate includes: the wiring substrate 11 provided in the embodiments of the present disclosure, driving elements IC bonded one-to-one to the first pad regions (not shown), and light-emitting elements bonded one-to-one to the pad groups (not shown) in the plurality of second pad regions (not shown).

In some embodiments, as shown in FIG. 9, the light-emitting substrate further includes: a circuit board bonded to the wiring substrate at the bonding region 102.

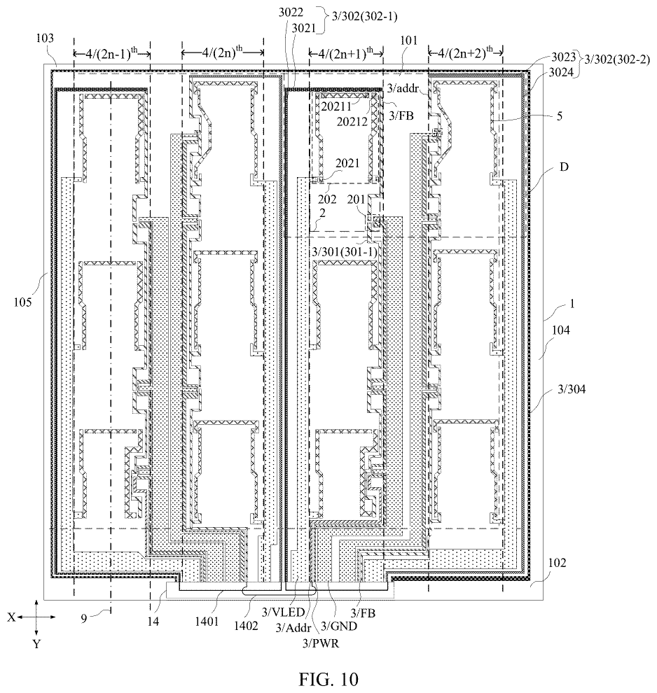

In some embodiments, as shown in FIG. 10, the circuit board 14 includes a plurality of first circuit structures 1401 and a plurality of second circuit structures 1402; the wiring substrate includes: pad unit columns 4, first transfer lines 302-1, second transfer lines 302-2, address lines addr and feedback lines FB.

The first transfer line 302-1 corresponding to the (2n−1)^{th} pad unit column 4 is electrically connected to the address line addr connected to the 2n^{th} pad unit column 4 through the first circuit structure 1401.

The second transfer line 302-2 corresponding to the 2n^{th} pad unit column 4 is electrically connected to the feedback line FB connected to the 2n^{th} pad unit column 4 through the second circuit structure 1402.

It should be noted that, in FIG. 10, the first transfer line 302-1 corresponding to the (2n−1)^{th} pad unit column 4 is electrically connected to the address line addr connected to the 2n^{th} pad unit column 4 through the first circuit structure 1401; the first transfer line 302-1 corresponding to the (2n+1)^{th} pad unit column 4 is electrically connected to the address line addr connected to the (2n+2)^{th} pad unit column 4 through the first circuit structure 1401; and the second transfer line 302-2 corresponding to the 2n^{th} pad unit column 4 is electrically connected to the feedback line FB connected to the 2n^{th} pad unit column 4 through the second circuit structure 1402. Thus, the (2n−1)^{th} pad unit column 4, the 2n^{th} pad unit column 4, the (2n+1)^{th} pad unit column 4 and the (2n+2)^{th} pad unit column 4 are cascaded through the feedback line FB, the first transfer line 302-1, the address line addr, the second transfer line 302-2, and the first circuit structure 1401 and the second circuit structure 1402 of the circuit board, so that the (2n−1)^{th} pad unit column 4, the 2n^{th} pad unit column 4, the (2n+1)^{th} pad unit column 4 and the (2n+2)^{th} pad unit column 4 form an addressing loop. The first circuit structure and the second circuit structure can be connection line structures made in the circuit board 14. The circuit board 14 can be any one of a hard printed circuit board or a flexible circuit board.

In some embodiments, the light-emitting element is a micro-sized inorganic light-emitting diode.

In a specific implementation, the micro-sized inorganic light-emitting diode is, e.g., a mini light-emitting diode (Mini-LED) or a micro light-emitting diode (Micro-LED). Mini-LED and Micro-LED are small in size and high in brightness, and can be widely used in display devices or their backlight modules. For example, the typical size (e.g., length) of Micro-LED is less than 100 microns, such as in a range of 10 microns to 80 microns; the typical size (e.g., length) of Mini-LED is in a range of 80 microns to 350 microns, such as 80 microns to 120 microns. The electronic element can be at least one of Micro-LED or Mini-LED.

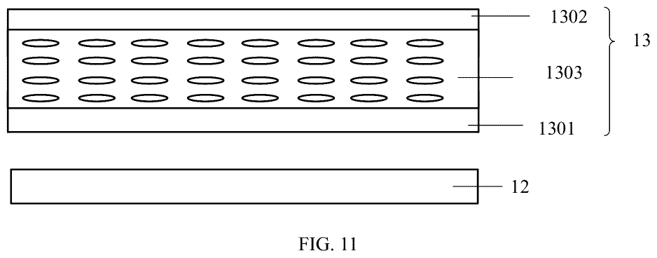

Based on the same inventive concept, an embodiment of the present disclosure further provides a display device, as shown in FIG. 11, including the light-emitting substrate 12 provided by the embodiment of the present disclosure.

In some embodiments, as shown in FIG. 11, the display device further includes: a display panel 13 on a light emergent side of the light-emitting substrate 12.

That is, the light-emitting substrate serves as the backlight source of the display panel.

In a specific implementation, as shown in FIG. 11, the display panel 13 is, e.g., a liquid crystal display panel, including: an array substrate 1301 and an opposite substrate 1302 that are oppositely arranged, and a liquid crystal layer 1303 located between the array substrate 1301 and the opposite substrate 1302.

The display device provided in the embodiments of the present disclosure is any product or component with a display function, such as a mobile phone, a tablet computer, a television, a display, a laptop computer, a digital photo frame, a navigator, etc. Other essential components of the display device should be understood by a person skilled in the art, and will not be described in detail here, nor should they be used as a limitation to the present disclosure. The implementation of the display device can refer to the embodiments of the wiring substrate and the light-emitting substrate mentioned above, and the repeated parts will not be described in detail.

In summary, in the wiring substrate, the light-emitting substrate and the display device provided by the embodiments of the present disclosure, one side of the first output line is adjacent to the first input line, and another side thereof is adjacent to another first output line or the second input line, that is, the first output line is not adjacent to the feedback line. Therefore, when the wiring substrate is applied to the light-emitting substrate, it can avoid the weak conduction between the feedback line and the first output line, which causes the conduction formed among the light-emitting device, the pad group, the feedback line and the first output line, thereby avoiding the light-emitting device from being lit, and avoiding the phenomenon of poor weak brightness of the light-emitting region corresponding to the cascaded final second pad region, thereby improving the display effect and enhancing user experience.

Although the preferred embodiments of the present invention have been described, those skilled in the art may make other changes and modifications to these embodiments once they have learned the basic creative concept. Therefore, the appended claims are intended to be interpreted as including the preferred embodiments and all changes and modifications that fall within the scope of the present invention.

Obviously, those skilled in the art can make various changes and modifications to the present disclosure without departing from the spirit and scope of the present disclosure. Thus, if these modifications and variations of the present disclosure fall within the scope of the claims of the present disclosure and their equivalents, the present disclosure is also intended to include these modifications and variations.

1. A wiring substrate, comprising: a base substrate, the base substrate being divided into a functional region and a bonding region; wherein
the functional region comprises a plurality of pad units arranged along a first direction and a second direction respectively, wherein the pad unit comprises: a first pad region, and a second pad region electrically connected to the first pad region, and the second direction intersects the first direction;
the functional region further comprises a plurality of routing lines arranged in the same one layer, wherein the plurality of routing lines comprise a plurality of first input lines, a plurality of first output lines, a plurality of second input lines, and a plurality of cascade lines;
input pads of a plurality of first pad regions arranged along the first direction are connected to the same one first input line, output pads of the plurality of first pad regions arranged along the first direction are connected to the same one first output line, two first pad regions that are adjacent to each other along the first direction are connected via the cascade line, and input ends of a plurality of second pad regions arranged along the first direction are connected to the same one second input line; and
in the functional region, in the second direction, one side of one first output line is adjacent to the first input line, and another side of the one first output line is adjacent to another first output line or the second input line.

2. The wiring substrate according to claim 1, wherein each of the first pad regions comprises a channel pad and an address pad, and in a plurality of cascaded first pad regions, a channel pad of an i^{th} stage first pad region and an address pad of an (i+1)^{th} stage first pad region are connected through the cascade line; wherein i is a positive integer.

3. The wiring substrate according to claim 2, wherein the plurality of pad units arranged along the first direction constitute a pad unit column, and the plurality of first pad regions in each pad unit column are sequentially cascaded along the first direction;
the plurality of routing lines further comprise a plurality of feedback lines; and
in at least part of the pad unit columns, a channel pad of a last stage first pad region among the plurality of cascaded first pad regions is connected to one of the feedback lines, and the feedback line is not adjacent to the first output line.

4. The wiring substrate according to claim 3, wherein a cascade direction of the plurality of first pad regions in one pad unit column is opposite to a cascade direction of the plurality of first pad regions in another pad unit column that is adjacent to the one pad unit column.

5. The wiring substrate according to claim 4, wherein a second input line and a first output line connected to a same one pad unit column are respectively on both sides of the same one pad unit column.

6. The wiring substrate according to claim 5, further comprising: 2N pad unit columns along the second direction; wherein
a first output line connected to a (2n−1)^{th} pad unit column is adjacent to a first output line connected to a 2n^{th} pad unit column; and
a second input line connected to a 2n^{th} pad unit column and a second input line connected to a (2n+1)^{th} pad unit column are oppositely arranged between the 2n^{th} pad unit column and a (2n+1)^{th} pad unit column;
wherein, N is a positive integer, and n is a positive integer not greater than N.

7. The wiring substrate according to claim 6, wherein the plurality of cascade lines comprise a plurality of first cascade lines and a plurality of second cascade lines; wherein
the first cascade lines cascade the pad units in the pad unit column in sequence; and
the second cascade line connects a last stage first pad region in the (2n−1)^{th} pad unit column to a first stage first pad region in the 2n^{th} pad unit column.

8. The wiring substrate according to claim 7, wherein the second cascade line comprises: a first portion, a second portion, and a third portion connected in sequence; wherein
at least a part of the first portion and at least a part of the third portion extend along the first direction, and the second portion extends along the second direction; and
the first portion is connected to a channel pad of the last stage first pad region in the (2n−1)^{th} pad unit column, and the third portion is connected to an address pad of the first stage first pad region in the 2n^{th} pad unit column.

9. The wiring substrate according to claim 8, wherein, in the first direction, the second portion is located on a side of the first output line away from the bonding region, the first portion is located on a side of the first output line electrically connected to the (2n−1)^{th} pad unit column away from the bonding region, and the third portion is located on a side of the first output line electrically connected to the 2n^{th} pad unit column away from the bonding region; and
the first output line electrically connected to the (2n−1)^{th} pad unit column is not adjacent to the first portion, and the first output line electrically connected to the 2n^{th} pad unit column is not adjacent to the third portion.

10. The wiring substrate according to claim 6, wherein
the plurality of routing lines further comprise a plurality of address lines and a plurality of transfer lines, the address line is connected to the address pad of the first stage first pad region in the pad unit column, and the channel pad of the last stage first pad region in the pad unit column is connected to the feedback line;
the plurality of transfer lines comprise a plurality of first transfer lines and a plurality of second transfer lines;
the first transfer line electrically connects a feedback line connected to the (2n−1)^{th} pad unit column with an address line connected to the 2n^{th} pad unit column; and
the second transfer line electrically connects a feedback line connected to the 2n^{th} pad unit column with an address line connected to the (2n+1)^{th} pad unit column;
wherein, N is a positive integer, and n is a positive integer not greater than N.

11. The wiring substrate according to claim 10, wherein the feedback line connected to the (2n−1)^{th} pad unit column is located on a side of the first output line connected to the (2n−1)^{th} pad unit column away from the bonding region;
the first transfer line comprises: a fourth portion extending along the second direction, and a fifth portion extending along the first direction in the functional region; wherein the feedback line connected to the (2n−1)^{th} pad unit column is connected to one end of the fourth portion, and the fifth portion is connected to another end of the fourth portion; and
the second input line connected to the (2n-1)^{th} pad unit column is adjacent to the fifth portion.

12. The wiring substrate according to claim 11, wherein the address line connected to the 2n^{th} pad unit column is located on a side of the first output line connected to the 2n^{th} pad unit column away from the bonding region;
the second transfer line comprises: a sixth portion extending along the second direction, and a seventh portion extending along the first direction in the functional region;
wherein the address line connected to the 2n^{th} pad unit column is connected to one end of the sixth portion, and the seventh portion is connected to another end of the sixth portion; and
the second input line connected to the 2n^{th} pad unit column is adjacent to the seventh portion.

13. The wiring substrate according to claim 12, wherein the fifth portion is adjacent to the seventh portion in a region between the second input line connected to the 2n^{th} pad unit column and the second input line connected to the (2n−1)^{th} pad unit column.

14. The wiring substrate according to claim 6, wherein the first pad region comprises the address pad, the input pad, the channel pad, and the output pad;
the address pad and the input pad are located in the same one row in the first direction, and the channel pad and the output pad are located in the same one row in the first direction; and the channel pad and the address pad are located in the same one column in the second direction, and the output pad and the input pad are located in the same one column in the second direction; and
in the (2n−1)^{th} pad unit column, the address pads and the input pads are located on a side of the channel pads and the output pads close to the bonding region in the first direction; and the first pad region in the 2n^{th} pad unit column after being rotated 180° is arranged in the same manner as the first pad region in the (2n−1)^{th} pad unit column;
wherein N is a positive integer and n is a positive integer not greater than N.

15. The wiring substrate according to claim 14, wherein among the address line, the first input line, and the first output line electrically connected to the (2n−1)^{th} pad unit column, the first input line is located between the address line and the first output line in the second direction; and
among the feedback line, the first input line, and the first output line corresponding to the 2n^{th} pad unit column, the first input line is located between the feedback line and the first output line in the second direction.

16. The wiring substrate according to claim 14, wherein the second pad region has a median line extending along the first direction; and
the first pad region in the (2n−1)^{th} pad unit column is located on a side of the median line facing the 2n^{th} pad unit column, and the first pad region in the 2n^{th} pad unit column is located on a side of the median line facing the (2n−1)^{th} pad unit column.

17. A light-emitting substrate, comprising: the wiring substrate according to claim 1, driving elements bonded one-to-one with the first pad regions, and light-emitting elements bonded one-to-one with a plurality of pad groups in the second pad regions.

18. The light-emitting substrate according to claim 17, further comprising:
a circuit board bonded to the wiring substrate in the bonding region; wherein the circuit board comprises a plurality of first circuit structures and a plurality of second circuit structures; and the wiring substrate comprises: pad unit columns, first transfer lines, second transfer lines, address lines, and feedback lines;
a first transfer line corresponding to a (2n−1)^{th} pad unit column is electrically connected to the address line connected to a 2n^{th} pad unit column through the first circuit structure; and
a second transfer line corresponding to the 2n^{th} pad unit column is electrically connected to a feedback line connected to the 2n^{th} pad unit column through the second circuit structure.

19. The light-emitting substrate according to claim 17, wherein the light-emitting element is a micro-sized inorganic light-emitting diode.

20. A display device, comprising: the light-emitting substrate according to claim 17.
